(19) United States
(12) Patent Application Publication
(10) Pub. No.: US 2014/0262461 A1
(43) Pub. Date: Sep. 18, 2014

(54) Process for Forming Self-Assembled Monolayer on Metal Surface and Printed Circuit Board Comprising Self-Assembled Monolayer

(71) Applicant: OMG Electronic Chemicals, Inc., South Plainfield, NJ (US)

(72) Inventors: Jim Trainor, Bethlehem, PA (US); Yubing Wang, Piscataway, NJ (US)

(73) Assignee: OMG Electronic Chemicals, Inc., South Plainfield, NJ (US)

(21) Appl. No.: 14/200,760

(22) Filed: Mar. 7, 2014

Related U.S. Application Data
(60) Provisional application No. 61/794,098, filed on Mar. 15, 2013.

(51) Int. Cl. H05K 3/28; H05K 1/09

(52) U.S. Cl. CPC H05K 3/282; H05K 1/09
USPC 174/257; 174/256; 427/96.2; 106/14.13

(57) ABSTRACT

The present invention provides a printed circuit board comprising a metal surface, such as a final finish, that has been coated with a self-assembled monolayer. The self-assembled monolayer forms a coating on the metal surface that is resistant to corrosion, thus preserving the solderability of the metal surface. The present invention also provides a solution of an alkanethiol and a non-organic solvent that can be used for forming a self-assembled monolayer on a metal substrate. The present invention also provides a process for depositing a self-assembled monolayer on a metal substrate by applying a solution of an alkanethiol and a non-organic solvent to a metal substrate, such as a surface of a printed circuit board.

The present application claims priority under 35 U.S.C. §119(e) to U.S. Provisional Application No. 61/794,098, filed on Mar. 15, 2013.

### BACKGROUND

1. Technical Field

The present technology generally relates to self-assembled monolayer coatings on metal surfaces and processes for forming self-assembled monolayer coatings on metal surfaces. Specifically, the present technology includes the formation of self-assembled monolayer coatings on the conductive surfaces of a printed circuit board.

2. Description of the Related Art

### Printed Circuit Boards

The term printed circuit boards refers to solid circuits that are formed from a conductive material (commonly, copper or copper plated with solder or gold) that is positioned on an insulating material (commonly glass-fiber-reinforced epoxy resin). Where the printed circuit board has two conductive surfaces position on opposite sides of a single insulating layer, the resulting circuit board is known as a “double sided circuit board.” To accommodate even more circuits on a single board, several copper layers are sometimes sandwiched between boards of insulating material to produce a multi-later circuit board. The conductive surfaces of a printed circuit board may also be populated with circuit elements and/or electronic components.

In order to make electrical connections between the circuits on opposite sides of a double-sided circuit board, a hole is first dilled through the double-sided circuit board, i.e. through the two conducting sheets and the insulator board. These holes are known as vias or “through holes.” Like the double-sided circuit boards, the multi-layer circuit boards use through holes to complete circuits between the circuit patterns. Through holes are used to mount electronic components on a side of a printed circuit board through the insertion of a pin (otherwise known as a lead) on the electronic component into the through hole and soldering of the pin to a pad on the opposite side of the printed circuit board. The through holes are often plated with copper.

Electronic components are attached to a printed circuit board through a process known as soldering. Soldering is a process that is used to bond similar or dissimilar materials by melting a filler metal or alloy that is placed between the components being joined. In the manufacture of printed circuit boards, soldering is used to make electrical connections to and between printed circuits. For example, an electronic connection between circuits using a through hole is typically carried out by coating the through hole walls and other conductive surfaces of a printed wiring board with hot, molten solder to make electrical connections by wetting and filling the spaces between the conductive through hole surfaces and the leads of electrical components with have been inserted through the through holes. Soldering inconsistencies, e.g. inconsistent or weak adherence to the conductive surfaces, are often the result of difficulties in keeping the conductive surfaces of the printed circuit board clean and free of tarnishing and corrosion prior to and during the soldering process.

A number of techniques to protect the solderability of the printed circuit board and prevent soldering inconsistencies have been developed. The most common involves the deposition of a coating of metal or a combination of metals on the conductive surfaces of the printed circuit board. The deposited metal coatings are often referred to as “final finishes.” Common “final finishes” include, for example, Electroless Nickel (EN), Electroless Palladium (EP), Electroless Nickel/Immersion Gold (ENIG), Electroless Nickel/Electroless Palladium/Immersion Gold (ENEPIG), Immersion Silver, and Electroless Nickel/Electroless Palladium (ENEP).

### Self-Assembled Monolayers

Self-assembled monolayers are organized molecular assemblies formed on surfaces. The molecules typically possess a functional group that has an affinity to the substrate, also known as a head group, and a tail group. In forming a self-assembled monolayer, the head groups of the molecules chemisorb to the substrate, arraying the tail groups to form a dense assembly that extends from the surface of the substrate. Known head groups include thiols, silanes, and phosphonates. In many applications, the tail group of the molecule is functionalized to provide the resulting monolayer with desired properties relating to, for example, wetting, adhesion, chemical resistance, biocompatibility, and the like. Due to the strong affinity of the thiol head group to metal substrates, alkanethiols have often been used in the formation of self-assembled monolayers. Alkanethiol self-assembled monolayers have found applications in electronics, for example, for modifying the surface properties of metal electrodes.

Alkanethiol self-assembled monolayers are typically applied to metal substrates by the interaction of an organic solution containing the alkanethiol and the metal substrate. For example, a solution is prepared by dispersing an alkanethiol in an organic solvent, such as ethanol. Then, a metal substrate is immersed in the alkanethiol solution and allowed to interact with the alkanethiol solution for a matter of time, depending on the desired packing of the self-assembled monolayer. A denser assembly is achieved with longer interaction times, which can range up to a number of days. Once the self-assembled monolayer has been deposited, the metal substrate is removed, rinsed with the organic solvent, and dried in an inert gas or nitrogen gas.

### SUMMARY

It has been found that in certain environments, the final finishes of printed circuit boards can, themselves, be subject to corrosion. Corrosion of the final finishes results in a decrease of the solderability of the printed circuit board. It has been found that a self-assembled monolayer applied as a coating on a conductive surface of a printed circuit board increases the resistance to corrosion of the surface and improves the solderability of the surface. Accordingly, in one feature of the present application, a printed circuit board having a conductive surface is coated with a self-assembled monolayer. The method and composition of embodiments of the present application are useful for providing a self-assembled monolayer on a conductive surface of a printed circuit board, such as one that has been treated to include a final finish, to prevent or minimize corrosion and to preserve solderability.

Due to the use of an organic solvent, the conventional process for forming self-assembled alkanethiol monolayers is unfeasible for applications in which the metal substrate should not come into contact with organic solvent. For example, a conventional organic solution of alkanethiol cannot be used to apply a self-assembled monolayer to the surface of a printed circuit board because the organic solvent attacks the solder mask of the printed circuit board. It has been found that self-assembled monolayers can be formed from a solution of alkanethiol dispersed in a non-organic solvent. Accordingly, another feature of the present application is directed to a solution for forming a self-assembled monolayer on a metal substrate. The solution comprises an alkanethiol, a non-organic solvent, and a surfactant operable to disperse the alkanethiol in the non-organic solvent.

Another feature of the present application is directed to a process for depositing a self-assembled monolayer on a metal substrate by providing a solution of alkanethiol in a non-organic solvent, and applying the solution to the metal substrate. For example, a metal substrate, such as an exposed surface of a printed circuit board, can be immersed in a bath of the alkanethiol solution to provide a self-assembled alkanethiol monolayer on the metal substrate.

One aspect of the present application a printed circuit board comprising a metal surface coated with a self-assembled monolayer. In embodiments of the printed circuit board, the self-assembled monolayer comprises an alkanethiol. In preferred embodiments of the printed circuit board, the alkanethiol is selected from the group consisting of hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, and octadecanethiol. For example, the alkanethiol is dodecanethiol in embodiments of the printed circuit board. In embodiments of the printed circuit board, the metal surface comprises nickel, gold, silver, palladium, copper, or combinations thereof. The metal surface of embodiments of the printed circuit board comprises a final finish, such as one selected from the group consisting of Electroless Nickel, Electroless Palladium, Electroless Nickel/Immersion Gold (ENIG), Electroless Nickel/Electroless Palladium (ENEP), Electroless Nickel/Electroless Palladium/Immersion Gold (ENEPIG), and Immersion Silver.

Another aspect of the present application is a solution for forming a self-assembled monolayer on a metal substrate, comprising an alkanethiol, a non-organic solvent, and a surfactant. In embodiments of the solution, the alkanethiol is selected from the group consisting of hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, and octadecanethiol. The non-organic solvent of embodiments of the solution is water. For example, embodiments of the solution comprise dodecanethiol, sodium dodecyl sulfate, and water. Embodiments of the solution also comprise a defoamer.

Another aspect of the present application is a process for depositing a self-assembled monolayer on a metal substrate, comprising providing a solution comprising an alkanethiol, a non-organic solvent, and a surfactant; and applying the solution to a metal substrate. In embodiments of the process, the solution is applied to the metal substrate by dipping, flooding, spraying, painting, or combinations thereof. In preferred embodiments, the solution is applied to the metal substrate by dipping, which may be performed at a temperature between about 25 and about 35° C. and for a length of time between about one minute and about five minutes.

In embodiments of the process, the alkanethiol is selected from the group consisting of hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, and octadecanethiol. The non-organic solvent of embodiments of the process is water. For example, embodiments of the process comprise a solution comprising dodecanethiol, sodium dodecyl sulfate, and water. In embodiments of the process, the metal substrate is a printed circuit board or a component of a printed circuit board.

Another aspect of the present application is the self-assembled monolayer formed by the process comprising providing a solution comprising an alkanethiol, a non-organic solvent, and a surfactant; and applying the solution to a metal substrate.

Another aspect of the present application is a method of preserving the solderability of a metal surface of a printed circuit board comprising forming a self-assembled monolayer on the metal surface. In embodiments of the method, the self-assembled monolayer comprises an alkanethiol. The metal surface of embodiments of the method comprises a final finish, such as one selected from the group consisting of Electroless Nickel, Electroless Palladium, Electroless Nickel/Immersion Gold (ENIG), Electroless Nickel/Electroless Palladium (ENEP), Electroless Nickel/Electroless Palladium/Immersion Gold (ENEPIG), and Immersion Silver.

### BRIEF DESCRIPTION OF THE DRAWINGS

A clear conception of the advantages and features of one or more embodiments will become more readily apparent by reference to the exemplary, and therefore non-limiting, embodiments illustrated in the drawings.

FIG. 1A is an image of a printed circuit board, showing water forming a film across a metal surface of the printed circuit board;

FIG. 1B is an image of a printed circuit board having a self-assembled monolayer coating in accordance with an embodiment of the present application, showing water forming a bead on a coated metal surface of the printed circuit board;

FIG. 2A is an image of a control sample having an ENIG final finish that was subjected to salt spray testing in accordance with Example 8, showing corrosion of both the wetting balance pads and the through holes;

FIG. 2B is an image of a test sample having a self-assembled monolayer coating on an ENIG final finish in accordance with an embodiment of the present application that was subjected to salt spray testing in accordance with Example 8, showing little to no corrosion of either the wetting balance pads or the through holes;

FIG. 3A is an image of a control sample having an ENEPIG final finish that was subjected to salt spray testing in accordance with Example 9, showing corrosion of both the wetting balance pads and the through holes;

FIG. 3B is an image of a test sample having a self-assembled monolayer coating on an ENEPIG final finish in accordance with an embodiment of the present application that was subjected to salt spray testing in accordance with Example 9, showing little to no corrosion of either the wetting balance pads or the through holes;

FIG. 4A is an image of a control sample having an Immersion Silver final finish that was subjected to SO₂ corrosion testing in accordance with Example 14, showing corrosion and extensive discoloration;

FIG. 4B is an image of a test sample having a self-assembled monolayer coating on an Immersion Silver final finish in accordance with an embodiment of the present application that was subjected to SO₂ corrosion testing in accordance with Example 14, showing no corrosion or discoloration;

FIG. 5A is an image of a control sample having an Electroless Palladium final finish that was subjected to SO₂ corrosion testing in accordance with Example 15, showing extensive corrosion and discoloration;

FIG. 5B is an image of a test sample having a self-assembled monolayer coating on an Electroless Palladium final finish in accordance with an embodiment of the present application that was subjected to SO₂ corrosion testing in accordance with Example 15, showing no corrosion or discoloration;

FIG. 6A is a graph showing the results of a wetting balance test on both a fresh test sample having a self-assembled monolayer coating (labeled post dip) in accordance with an embodiment of the present application and a fresh control sample (labeled control);

FIG. 6B is a graph showing the results of a wetting balance test on both a test sample having a self-assembled monolayer coating (labeled post dip) in accordance with an embodiment of the present application and a control sample (labeled control), both of which having been artificially aged by being subjected to the 24 hour SO₂ corrosion test.

### DETAILED DESCRIPTION

In order to create a self-assembled monolayer (SAM) on a on a metal surface such as a printed circuit board, a non-organic solution of a SAM-forming molecule was prepared. The SAM-forming molecule may be an alkanethiol—a molecule having a thiol head group and an alkane tail group. Preferably, the alkane tail group of the alkanethiol comprises between six carbon atoms and eighteen carbon atoms, although both shorter and longer alkane tail groups are also contemplated. In other words, the alkanethiol is preferably selected from the group consisting of hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, and octadecanethiol. A particularly preferred alkanethiol is dodecanethiol, an alkanethiol comprising an alkane tail group having twelve carbon atoms.

An alkanethiol may be dispersed in a non-organic solvent, to form a solution that is useful for coating a metal substrate with a self-assembled monolayer. For most applications, the non-organic solvent may be water. In order to disperse the alkanethiol in a non-organic solvent, such as water, a suitable surfactant is needed. A suitable surfactant has a carbon chain that is similar to the alkane tail of the specific alkanethiol being dispersed. For example, sodium dodecyl sulfate (the salt of an organosulfate comprising a tail having twelve carbon atoms) is a suitable surfactant for dispersing dodecanethiol in water. Yet, the same sodium dodecyl sulfate may not be suitable to disperse hexanethiol—an alkanethiol having an alkane tail group comprising six carbon atoms—in water.

The solution comprises an alkanethiol, a non-organic solvent, and a surfactant that is suitable to disperse the alkanethiol in the non-organic solvent. The concentration of the alkanethiol in the solution is preferably at least 0.0001 gram per liter. More preferably, the concentration of the alkanethiol in the solution is between about 0.01 gram per liter and 100 gram per liter. More preferably, the concentration of the alkanethiol in the solution is between about 0.1 gram per liter and 10 gram per liter. To ensure that the desired amount of alkanethiol is completely dispersed in the solution, the surfactant is preferably present in an amount of at least about ten times the amount of alkanethiol. For example, to provide a solution comprising 1 gram per liter alkanethiol, at least about 10 gram per liter of a suitable surfactant is supplied. Alternatively, the surfactant may be present in an amount of at least about twenty times the amount of alkanethiol.

In some embodiments, the solution also comprises a defoamer. For example, small amounts of an organic compound that is capable as acting as a defoamer may be supplied. By minimizing foaming when the solution is agitated (such as by stifling or pumps), the organic compound may serve to make it easier to form the solution and/or to apply the solution to a metal substrate, for example by dipping a metal substrate into a bath containing the solution. The small amounts of organic compound have the additional benefit of reducing the amount of surfactant that is needed to disperse the alkanethiol. Thus, the use of small amounts of an organic compound can provide cost savings, as the organic compounds are typically less expensive than the surfactants contemplated herein. Examples of suitable organic compounds include diethylene butyl ether, ethanol, isopropyl alcohol, combinations of the above, and other organic compounds that may be generally available as organic solvents. Any organic compound which acts as a defoamer and/or serves to aid in the dispersion of the alkanethiol in the non-organic solvent is contemplated.

The organic compound is preferably present in the aqueous alkanethiol-containing solution in an amount of less than 15% of the total weight of the solution. Alternatively the organic compound is present in an amount of less than 10% of the total weight of the solution, alternatively the organic compound is present in an amount of less than 8% of the total weight of the solution, alternatively the organic compound is present in an amount of less than 6% of the total weight of the solution, alternatively the organic compound is present in an amount of less than 5% of the total weight of the solution, alternatively the organic compound is present in an amount of less than 4% of the total weight of the solution, alternatively the organic compound is present in an amount of less than 3% of the total weight of the solution. The small amounts of organic compound contemplated for the formation of a self-assembled monolayer on a printed circuit board are too minor to have any undesirable effect on the solder mask of a printed circuit board. For the formation of a self-assembled monolayer on a printed circuit board, the organic compound is generally present in the solution in an amount of less than 5% of the total weight of the solution, although the maximum amount may vary depending on which organic compound is used.

Preparation of the alkanethiol-containing solution may be carried out by any suitable means. Preferably, the surfactant and, if being used the organic compound, should be added and mixed with the non-organic solvent (such as water) prior to addition of the alkanethiol. Once the surfactant has been mixed into the non-organic solvent, the alkanethiol is added and the mixture is vigorously stirred to disperse the alkanethiol and form the solution. Up to ten minutes may be necessary before the alkanethiol is fully dispersed in the non-organic solvent. Heat may be applied to aid in the formation of the solution, but is generally not necessary. If heat is applied, the temperature of the solution should be carefully monitored to ensure that the materials do not begin to break down (which can occur at high temperatures).

To form a self-assembled monolayer on a metal substrate, the solution of alkanethiol is provided and applied to a metal substrate at conditions suitable for the chemisorption of the thiol head group to the metal surface. The solution is preferably applied to the metal substrate by dip coating. For example, the metal substrate may be dipped into a bath containing the alkanethiol solution, and submerging the metal substrate in the alkanethiol-containing solution for a period of time known as the dwell time. It may often be desirable to produce and store a concentrated solution of the alkanethiol and then dilute the concentrated solution with water to form the bath. Other methods of applying the solution to a metal substrate are also contemplated. For example, the alkanethiol-containing solution may be applied to a metal substrate by flooding, spraying, painting, and the like.

The amount of time in which the metal substrate and the alkanethiol-containing solution interact, i.e. the dwell time, is selected depending on the desired density of the self-assembled monolayer. A self-assembled monolayer having a denser assembly is achieved with longer dwell times. However, at some point, the increases in density are outweighed by the increased manufacturing time. The dwell time may range between one second and a number of days. Preferably, the dwell time is between about 15 seconds and one hour. More preferably, the dwell time is between about 15 seconds and 30 minutes. More preferably, the dwell time is between about 30 seconds and 10 minutes. More preferably, the dwell time is between about 30 seconds and 5 minutes. More preferably, the dwell time is between about one minute and 5 minutes.

Formation of the self-assembled monolayer may also be affected by temperature. An alkanethiol monolayer will form at almost any temperature, however, for optimum monolayer formation the solution is preferably maintained at a temperature between about 15° and 50° C. More preferably, the solution is maintained at a temperature between about 20° and 40° C. More preferably, the solution is maintained at a temperature between about 25° and 35° C.

Self-assembled monolayers may be formed on any metal substrate using the composition and process described herein. Examples of possible metal substrates include nickel, gold, silver, palladium, copper, and combinations thereof. The invention is not limited to the embodiments described below.

Embodiments of the present application are directed to the formation of a self-assembled monolayer on a surface of a printed circuit board. Preferably, the self-assembled monolayer is an alkanethiol monolayer. The self-assembled monolayer is preferably formed on a final finish metal coating that has been applied to the conductive surface of a printed circuit board. For example, the final finish may be selected from the group consisting of Electroless Nickel (EN), Electroless Palladium (EP), Electroless Nickel/Immersion Gold (ENIG), Electroless Nickel/Electroless Palladium/Immersion Gold (ENEPIG), Immersion Silver, and Electroless Nickel/Electroless Palladium (ENEP). The self-assembled monolayer may also be formed directly on the conductive surface (commonly copper) of a printed circuit board.

A printed circuit board comprising a self-assembled monolayer coating has an increased resistance to corrosion. This effect is achieved because the dense assembly of the alkane tail groups of the self-assembled alkanethiol monolayer forms a barrier to moisture and other corrosion-causing contaminants. Thus, a denser assembly provides a better barrier and provides an enhanced protection against corrosion. This protection against corrosion gives the printed circuit board a superior solderability.

The self-assembled monolayer is preferably formed by the interaction of the printed circuit board with a non-organic solution of alkanethiol, such as in the manner described above. The alkanethiol-containing solution may be applied to the printed circuit board at any time. For example, the self-assembled monolayer may be formed on a printed circuit board anytime during its lifespan. Preferably, the alkanethiol-containing solution is applied during the manufacture of a printed circuit board. For example, the alkanethiol-containing solution may be applied to the printed circuit board immediately following a final finish plating.

The printed circuit board is preferably rinsed prior to application of the alkanethiol-containing solution. For example, the printed circuit board may be rinsed with water. Then, in a preferred embodiment, the printed circuit board is dipped into a tank that is filled with the alkanethiol-containing solution. The solution is preferably maintained at a desired operating temperature and the printed circuit board is submerged for a desired dwell time. Once the printed circuit board and the alkanethiol solution have interacted such that a suitably dense self-assembled monolayer has formed on the surface of the printed circuit board, the printed circuit board is removed from the alkanethiol-containing solution and rinsed with, for example, water to remove any excess solution. The printed circuit board may then be blown dry.

The presence of a self-assembled monolayer on a surface, such as a surface of a printed circuit board, may be determined by any known method, including x-ray photoelectron spectroscopy, infrared spectroscopy, ellipsometry, contact angle analysis, and UV analysis. For determining the presence of an alkanethiol self-assembled monolayer on the surface of a printed circuit board, however, a simple water test may be sufficient. When water is present on the conductive surfaces of a standard printed circuit board (i.e. one that has not been coated with a self-assembled monolayer), the water will tend to form a film across the surface, indicating that the surface is hydrophilic. This effect is illustrated, for example, in FIG. 1A. However, when water is present on the conductive surfaces of a printed circuit board that has been treated as described herein, the water will tend to form beads, indicating that the surface is hydrophobic. This effect is illustrated, for example, in FIG. 1B. The observation of water beads demonstrates that a self-assembled monolayer has formed on the treated surface and has brought about a change in the properties of the surface from hydrophilic to hydrophobic.

A person familiar with the technology will understand that the conditions described above can be varied and adjusted to achieve a desired self-assembled monolayer on a metal substrate.

### Example 1

### Preparation of Solution of Dodecanthiol in Water

In one non-limiting embodiment, a solution of dodecanthiol in water was prepared. To one liter (1000 grams) of deionized water, 120 grams of sodium dodecyl sulfate and 150 grams of diethylene butyl ether were added and dispersed by stifling. Then, 5 grams of dodecanethiol was added and the mixture was stirred vigorously for a period of between five and ten minutes until the dodecanethiol was completely dispersed. The resulting solution was clear (not cloudy) and had a color that fell within the spectrum from neutral, i.e. no color, to slightly yellow.

### Example 2

### Formation of Self-Assembled Monolayer on PCB with ENIG Final Finish

In one non-limiting embodiment, a printed circuit board having a self-assembled monolayer coating on an Electroless Nickel/Immersion Gold (ENIG) final finish was prepared. A printed circuit board having an Electroless Nickel/Immersion Gold (ENIG) final finish was rinsed with deionized water and dipped into a bath containing the solution of Example 1 diluted with deionized water. Specifically, the bath contained the solution of Example 1 in an amount of about 25% by volume, the remaining 75% by volume being deionized water. The bath was maintained at a temperature of about 30° C. (the temperature being controlled between the limits of 25° to 35° C.). The bath was also mildly agitated by a pump. The printed circuit board was submerged in the bath for about 3 minutes. After 3 minutes, the printed circuit board was removed from the bath and rinsed with deionized water. It was then blown dry.

The printed circuit board was examined by adding a few drops of water to one of the treated surfaces. It was observed that the water beaded on the treated surfaces, demonstrating that the surface had been rendered hydrophobic by the coating of a self-assembled monolayer of alkanethiol.

### Example 3

### Formation of Self-Assembled Monolayer on PCB with ENEPIG Final Finish

In one non-limiting embodiment, a printed circuit board having a self-assembled monolayer coating on an Electroless Nickel/Electroless Palladium/Immersion Gold (ENEPIG) final finish was prepared. A printed circuit board having an Electroless Nickel/Electroless Palladium/Immersion Gold (ENEPIG) final finish was rinsed with deionized water and dipped into a bath containing the solution of Example 1 diluted with deionized water. Specifically, the bath contained the solution of Example 1 in an amount of about 20% by volume, the remaining 80% by volume being deionized water. The bath was maintained at a temperature of about 30° C. (the temperature being controlled between the limits of 25° to 35° C.). The bath was also mildly agitated by a pump. The printed circuit board was submerged in the bath for about 3 minutes. After 3 minutes, the printed circuit board was removed from the bath and rinsed with deionized water. It was then blown dry.

The printed circuit board was examined by adding a few drops of water to one of the treated surfaces. It was observed that the water beaded on the treated surfaces, demonstrating that the surface had been rendered hydrophobic by the coating of a self-assembled monolayer of alkanethiol.

### Example 4

### Formation of Self-Assembled Monolayer on PCB with Immersion Ag Final Finish

In one non-limiting embodiment, a printed circuit board having a self-assembled monolayer coating on an Immersion Silver final finish was prepared. A printed circuit board having an Immersion Silver final finish was rinsed with deionized water and dipped into a bath containing the solution of Example 1 diluted with deionized water. Specifically, the bath contained the solution of Example 1 in an amount of about 20% by volume, the remaining 80% by volume being deionized water. The bath was maintained at a temperature of about 30° C. (the temperature being controlled between the limits of 25° to 35° C.). The bath was also mildly agitated by a pump. The printed circuit board was submerged in the bath for about 3 minutes. After 3 minutes, the printed circuit board was removed from the bath and rinsed with deionized water. It was then blown dry.

The printed circuit board was examined by adding a few drops of water to one of the treated surfaces. It was observed that the water beaded on the treated surfaces, demonstrating that the surface had been rendered hydrophobic by the coating of a self-assembled monolayer of alkanethiol.

### Example 5

### Formation of Self-Assembled Monolayer on PCB with Electroless Pd Final Finish

In one non-limiting embodiment, a printed circuit board having a self-assembled monolayer coating on an Electroless Palladium final finish was prepared. A printed circuit board having an Electroless Palladium final finish was rinsed with deionized water and dipped into a bath containing the solution of Example 1 diluted with deionized water. Specifically, the bath contained the solution of Example 1 in an amount of about 20% by volume, the remaining 80% by volume being deionized water. The bath was maintained at a temperature of about 30° C. (the temperature being controlled between the limits of 25° to 35° C.). The bath was also mildly agitated by a pump. The printed circuit board was submerged in the bath for about 3 minutes. After 3 minutes, the printed circuit board was removed from the bath and rinsed with deionized water. It was then blown dry.

The printed circuit board was examined by adding a few drops of water to one of the treated surfaces. It was observed that the water beaded on the treated surfaces, demonstrating that the surface had been rendered hydrophobic by the coating of a self-assembled monolayer of alkanethiol.

### Example 6

### Formation of Self-Assembled Monolayer on PCB with Electroless Ni Final Finish

In one non-limiting embodiment, a printed circuit board having a self-assembled monolayer coating on an Electroless Nickel final finish was prepared. A printed circuit board having an Electroless Nickel final finish was rinsed with deionized water and dipped into a bath containing the solution of Example 1 diluted with deionized water. Specifically, the bath contained the solution of Example 1 in an amount of about 20% by volume, the remaining 80% by volume being deionized water. The bath was maintained at a temperature of about 30° C. (the temperature being controlled between the limits of 25° to 35° C.). The bath was also mildly agitated by a pump. The printed circuit board was submerged in the bath for about 3 minutes. After 3 minutes, the printed circuit board was removed from the bath and rinsed with deionized water. It was then blown dry.

The printed circuit board was examined by adding a few drops of water to one of the treated surfaces. It was observed that the water beaded on the treated surfaces, demonstrating that the surface had been rendered hydrophobic by the coating of a self-assembled monolayer of alkanethiol.

### Example 7

### Formation of Self-Assembled Monolayer on Copper Surface of PCB

In one non-limiting embodiment, a printed circuit board having a self-assembled monolayer coating on a copper surface was prepared. A printed circuit board having a copper conductive surface was rinsed with deionized water and dipped into a bath containing the solution of Example 1 diluted with deionized water. Specifically, the bath contained the solution of Example 1 in an amount of about 20% by volume, the remaining 80% by volume being deionized water. The bath was maintained at a temperature of about 30° C. (the temperature being controlled between the limits of 25° to 35° C.). The bath was also mildly agitated by a pump. The printed circuit board was submerged in the bath for about 3 minutes. After 3 minutes, the printed circuit board was removed from the bath and rinsed with deionized water. It was then blown dry.

The printed circuit board was examined by adding a few drops of water to one of the treated surfaces. It was observed that the water beaded on the treated surfaces, demonstrating that the surface had been rendered hydrophobic by the coating of a self-assembled monolayer of alkanethiol.

### Protection Against Corrosion

Printed circuit board test samples having various final finishes were coated with self-assembled monolayers and subjected to a corrosion protection evaluation. Corrosion resistance was evaluated using both salt spray testing and SO₂ testing. As a control group, printed circuit board samples having final finishes that were not coated with a self-assembled monolayer were simultaneously subjected to the same evaluation.

The salt spray test is a standardized test method used to evaluate the corrosion resistance of metals and/or coated metals. The salt spray test is an accelerated corrosion test that produces a corrosive attack to the coated metals in order to predict the suitability of the coating as a protective finish. The test is performed in a closed testing chamber, where a salted solution is atomized by means of a nozzle. The test was performed with a standardized solution of 5% sodium chloride (making it a neutral salt spray test) at a temperature of 35° C. This produces a corrosive environment of dense saline fog in the chamber so that parts exposed to it are subjected to severely corrosive conditions. Printed circuit board test samples comprising through holes and wetting balance pads and having various final finishes were coated with self-assembled monolayers and subjected to a corrosion protection evaluation. The appearance of corrosion products (oxides) was evaluated after 96 hours.

### Example 8

### Salt Spray Testing of Self-Assembled Monolayer on PCB with ENIG Final Finish

The salt spray test was performed on both (a) a printed circuit board test sample containing an ENIG final finish and having been coated with a self-assembled monolayer by the procedure described in Example 2 and (b) a printed circuit board control sample containing an ENIG final finish. After 96 hours, the test sample and the control sample were evaluated. The control sample underwent significant to extensive corrosion in through hole areas while the test sample comprising the self-assembled monolayer displayed little to no corrosion in the through hole areas. Additionally, the control sample underwent corrosion on the wetting balance pads while the test sample comprising the self-assembled monolayer displayed minimal corrosion on the wetting balance pads. The results of this salt spray testing are illustrated, for example, in FIGS. 2A and 2B.

### Example 9

### Salt Spray Testing of Self-Assembled Monolayer on PCB with ENEPIG Final Finish

The salt spray test was performed on both (a) a printed circuit board test sample containing an ENEPIG final finish and having been coated with a self-assembled monolayer by the procedure described in Example 2 and (b) a printed circuit board control sample containing an ENEPIG final finish. After 96 hours, the test sample and the control sample were evaluated. The control sample underwent extensive corrosion in through hole areas while the test sample comprising the self-assembled monolayer displayed little to no corrosion in the through hole areas. Additionally, the control sample underwent corrosion on the wetting balance pads while the test sample comprising the self-assembled monolayer displayed minimal corrosion on the wetting balance pads. The results of this salt spray testing are illustrated, for example, in FIGS. 3A and 3B.

### Example 10

### Salt Spray Testing of Self-Assembled Monolayer on PCB with Immersion Ag Final Finish

The salt spray test was performed on both (a) a printed circuit board test sample containing an Immersion Silver final finish and having been coated with a self-assembled monolayer by the procedure described in Example 2 and (b) a printed circuit board control sample containing an Immersion Silver final finish. After 96 hours, the test sample and the control sample were evaluated. The control sample underwent significant amounts of corrosion in through hole areas while the test sample comprising the self-assembled monolayer displayed little to no corrosion in the through hole areas. Additionally, the control sample underwent significant amounts of corrosion on the wetting balance pads while the test sample comprising the self-assembled monolayer displayed little to no corrosion on the wetting balance pads.

### Example 11

### Salt Spray Testing of Self-Assembled Monolayer on PCB with Electroless Pd Final Finish

The salt spray test was performed on both (a) a printed circuit board test sample containing an Electroless Palladium final finish and having been coated with a self-assembled monolayer by the procedure described in Example 2 and (b) a printed circuit board control sample containing an Electroless Palladium final finish. After 96 hours, the test sample and the control sample were evaluated. The control sample underwent significant to extensive corrosion and staining in through hole areas while the test sample comprising the self-assembled monolayer displayed only minimal staining in the through hole areas. Additionally, the control sample underwent significant to extensive corrosion and staining on the wetting balance pads while the test sample comprising the self-assembled monolayer displayed only minimal staining on the wetting balance pads.

### Example 12

### Salt Spray Testing of Self-Assembled Monolayer on PCB with Electroless Ni Final Finish

The salt spray test was performed on both (a) a printed circuit board test sample coupon (lacking through holes) having an Electroless Nickel final finish and having been coated with a self-assembled monolayer by the procedure described in Example 2 and (b) a printed circuit board control sample coupon (lacking through holes) having only an Electroless final finish. After 24 hours, the test sample and the control sample were evaluated. The control sample underwent significant discoloration while the test sample comprising the self-assembled monolayer displayed only minimal discoloration.

The SO₂ test is another standardized test method used to evaluate the corrosion resistance of metals and/or coated metals. Briefly, a test sample is placed in a closed container, into which about 10 ppm of SO₂ is continuously generated and maintained. The closed container is kept under this SO₂-containing atmosphere at a temperature of about 42° C. for a period of about 24 hrs. After about 24 hours, the test samples are removed from the container and examined, such as with a microscope having about ten time (10×) magnification.

More particularly, test sample coupons and control sample coupons were cut to a proper size and mounted on a perforated plate (such as using non corrosive clips) so as to stand vertically away from the plate. Each coupon on the plate was separated from all other test samples by at least about one inch. The chemicals used for generating the SO₂ gas—specifically sodium sulfite (Na₂SO₃), potassium phosphate monobasic (KH₂PO₄) and potassium phosphate dibasic (K₂HPO₄)—were mixed in appropriate amounts to form a solution and transferred into a pre-heated desiccator. The plate having the test samples mounted thereon was then placed in the desiccator, such that the test samples stood vertically above the chemical solution. The desiccator was immediately sealed and placed into an oven. After about fifteen minutes, the cap of the desiccator was opened slightly to release the pressure. The desiccator was then resealed and kept in the oven for a 24 hour period. After the 24 hour period, the desiccator was removed from the oven, put under a vacuum hood and opened. The test samples were dried with air and examined.

### Example 13

### SO₂ Testing of Self-Assembled Monolayer on PCB with ENIG Final Finish

The SO₂ corrosion test was performed on both (a) a printed circuit board test sample containing an ENIG final finish and having been coated with a self-assembled monolayer by the procedure described in Example 2 and (b) a printed circuit board control sample containing an ENIG final finish. After 24 hours, the control samples displayed discoloration and staining. The test samples that were treated so as to contain a self-assembled monolayer coating, on the other hand, did not display any changes.

### Example 14

### SO₂ Testing of Self-Assembled Monolayer on PCB with Immersion Ag Final Finish

The SO₂ corrosion test was performed on both (a) a printed circuit board test sample containing an Immersion Silver final finish and having been coated with a self-assembled monolayer by the procedure described in Example 2 and (b) a printed circuit board control sample containing an Immersion Silver final finish. After 24 hours, the control samples displayed corrosion and extensive discoloration. The test samples that were treated so as to contain a self-assembled monolayer coating, on the other hand, did not display any changes. The results of this SO₂ corrosion testing are illustrated, for example, in FIGS. 4A and 4B.

### Example 15

### SO₂ Testing of Self-Assembled Monolayer on PCB with Electroless Pd Final Finish

The SO₂ corrosion test was performed on both (a) a printed circuit board test sample containing an Electroless Palladium final finish and having been coated with a self-assembled monolayer by the procedure described in Example 2 and (b) a printed circuit board control sample containing an Electroless Palladium final finish. In order to test the ability of the self-assembled monolayer coating to preserve a metal surface under a condition that would ordinarily result in aggressive corrosion, the test sample and control sample coupons were provided with an Electroless Palladium deposit having half the standard thickness. Thus, the Electroless Palladium finish of the test and control samples was each only about 2 microns thick, instead of the standard 4 micron thickness. After 24 hours, the control samples displayed extensive corrosion and discoloration. The test samples that were treated so as to contain a self-assembled monolayer coating, on the other hand, did not display any changes. The results of this SO₂ corrosion testing are illustrated, for example, in FIGS. 5A and 5B.

### Preservation of Solderability

Printed circuit board test samples having various final finishes were coated with self-assembled monolayers and subjected to a solderability evaluation. Solderability was evaluated using a standard wetting balance analysis. The solderability of a surface is defined by its solder wetting characteristics. Solder wetting pertains to the formation of a relatively uniform, smooth, and unbroken film of solder that exhibits excellent adherence on the soldered surface. Non-wetting, on the other hand, is the condition wherein the solder coating has contacted the surface but did not adhere completely to it, causing the surface or a part thereof to be exposed. The wetting balance analysis is a quantitative test that measures the wetting forces between molten solder and the test surface as a function of time.

More particularly, the test samples were attached to a very sensor and immersed at a controlled rate into a solder pot. The samples were then held in the solder pot for a pre-determined period of time, during which the wetting forces were detected by the sensor, and then withdrawn at a controlled rate. As a control group, printed circuit board samples having final finishes that were not coated with a self-assembled monolayer were simultaneously subjected to the same analysis. The test samples and the control samples were analyzed at two different phases: (1) as fresh (i.e. unaged) coupons and (2) after undergoing the SO₂ corrosion test described above. The results of the wetting balance test may be understood by reference to the exemplary graphs of FIGS. 6A and 6B.

FIG. 6A illustrates the results from each of a fresh test sample having a self-assembled monolayer coating (labeled post-dip), and a corresponding fresh control sample that lacks a self-assembled monolayer coating (labeled control). For each, the plot starts with the wetting force being negative (non-wet condition), and then rises until it crosses the zero axis of wetting force, indicating that wetting has occurred. After a number of seconds, the plot for each then begins to level off, indicating that the maximum wetting potential of the surface has been reached. Because the plot for the test sample and the plot for the control sample have similar plots and maximum wetting potentials, it has been shown that the coating of a metal surface with a self-assembled monolayer poses no negative effect to the solderability of a metal surface.

FIG. 6B illustrates the results from each of a test sample having a self-assembled monolayer coating (labeled post-dip), and a corresponding control sample that lacks a self-assembled monolayer coating (labeled control). This time, however, each sample has been subjected to the SO₂ corrosion test described above, which replicates an accelerated aging and corrosion process. Notably, the control sample never crosses the zero axis of wetting force, indicating that wetting never occurs. Rather the control sample levels off at a negative wetting force, or non-wetting condition. In short, the control sample lacks solderability. The test sample, on the other hand, crosses the zero axis of wetting force after about one second and levels out at a maximum wetting force of about 0.1 mN/mm, displaying a maximum wetting potential only about 0.05 mN/mm less than the maximum wetting potential of fresh test sample. Thus, the self-assembled monolayer has been shown to preserve the solderability of a metal under a harsh environment, such as one which may otherwise render a metal non-solderable.

### High Temperature and High Humidity Age Testing

The high temperature and high humidity accelerated aging test is another standardized test method used to evaluate the capacity of a metal and/or coated metal to maintain its solderability over an extended period of time. A test sample is placed under high temperature and high humidity conditions for a number of hours. The conditions are selected to produce an accelerated aging of the test sample. The accelerated aging of the test sample under the high temperature and high humidity conditions is designed to replicate the effects that would be produced slowly over time under conventional conditions, such as during an extended storage of a printed circuit board.

Here, test samples were placed in a closed container, in which the atmosphere was brought to and maintained at 85° C. and at a relative humidity of about 85%. The closed container was kept under this atmosphere for a period of about 8 hours. After about 8 hours, the test samples are removed from the container and examined, such as with a conventional light microscope at 10× and 20× magnification.

### Example 16

### Testing of Self-Assembled Monolayer on Copper Surface of PCB

The high temperature and high humidity accelerated aging test was performed on both (a) a printed circuit board test sample containing a copper surface and having been coated with a self-assembled monolayer by the procedure described in Example 7 and (b) a printed circuit board control sample containing a copper surface. After 8 hours, the control samples displayed significant discoloration, an indication of heavy oxidation. The test samples that were treated so as to contain a self-assembled monolayer coating, on the other hand, did not display any indication of oxidation.

### Example 17

### Testing of Self-Assembled Monolayer on PCB with ENIG Final Finish

The high temperature and high humidity accelerated aging test was performed on both (a) a printed circuit board test sample containing an ENIG final finish and having been coated with a self-assembled monolayer by the procedure described in Example 2 and (b) a printed circuit board control sample containing an ENIG final finish. After 8 hours, the control samples displayed slight discoloration, indicating that some oxidation had occurred. The test samples that were treated so as to contain a self-assembled monolayer coating, on the other hand, did not display any indication of oxidation.

### Example 18

### Testing of Self-Assembled Monolayer on PCB with Electroless Pd Final Finish

The high temperature and high humidity accelerated aging test was performed on both (a) a printed circuit board test sample containing an Electroless Palladium final finish and having been coated with a self-assembled monolayer by the procedure described in Example 5 and (b) a printed circuit board control sample containing an Electroless Palladium final finish. After 8 hours, the control samples displayed slight discoloration, indicating that some oxidation had occurred. The test samples that were treated so as to contain a self-assembled monolayer coating, on the other hand, did not display any indication of oxidation.

The printed circuit board test samples and control samples from Examples 16, 17, and 18 were also evaluated for solderability. The test samples and the control samples were analyzed at two different phases: (1) as fresh (i.e. unaged) coupons and (2) after undergoing the high temperature and high humidity accelerated age testing described above. The results confirmed the solderability preserving character of the self-assembled monolayer, previously demonstrated for example in FIGS. 6A and 6B.

Specifically, the self-assembled monolayer was demonstrated to preserve the solderability of a bare copper substrate after being subjected to eight hours of high temperature and high humidity aging. The control sample, on the other hand, became almost non-solderable after accelerated aging. The self-assembled monolayer was also demonstrated to improve the solderability of the ENIG final finish and the Electroless Palladium final finish after each was subjected to high temperature and high humidity accelerated aging. There was even some indication that the self-assembled monolayer enhanced the solderability of the fresh coupon having the Electroless Palladium final finish.

It can be seen that the described embodiments provide a unique and novel self-assembled monolayer solution and coating that has a number of advantages over those in the art. While there is shown and described herein certain specific structures embodying the invention, it will be manifest to those skilled in the art that various modifications and rearrangements of the parts may be made without departing from the spirit and scope of the underlying inventive concept and that the same is not limited to the particular forms herein shown and described except insofar as indicated by the scope of the appended claims.

What is claimed:

1. A printed circuit board comprising a metal surface coated with a self-assembled monolayer.

2. The printed circuit board of claim 1, wherein the self-assembled monolayer comprises an alkanethiol.

3. The printed circuit board of claim 2, wherein the alkanethiol is selected from the group consisting of hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, and octadecanethiol.

4. The printed circuit board of claim 3, wherein the alkanethiol is dodecanethiol.

5. The printed circuit board of claim 1, wherein the metal surface comprises nickel, gold, silver, palladium, copper, or combinations thereof.

6. The printed circuit board of claim 1, wherein the metal surface comprises a final finish.

7. The printed circuit board of claim 6, wherein the final finish is selected from the group consisting of Electroless Nickel, Electroless Palladium, Electroless Nickel/Immersion Gold (ENIG), Electroless Nickel/Electroless Palladium (ENEP), Electroless Nickel/Electroless Palladium/Immersion Gold (ENEPIG), and Immersion Silver.

8. A solution for forming a self-assembled monolayer on a metal substrate, comprising:
(a) an alkanethiol;
(b) a non-organic solvent; and
(c) a surfactant.

9. The solution of claim 8, wherein the alkanethiol is selected from the group consisting of hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, and octadecanethiol.

10. The solution of claim 8, wherein the non-organic solvent is water.

11. The solution of claim 10, wherein the alkanethiol is dodecanethiol and the surfactant is sodium dodecyl sulfate.

12. The solution of claim 8, further comprising a defoamer.

13. A process for depositing a self-assembled monolayer on a metal substrate, comprising:
(a) providing the solution of claim 8; and
(b) applying the solution to a metal substrate.

14. The process of claim 13, wherein the solution is applied to the metal substrate by dipping, flooding, spraying, painting, or combinations thereof.

15. The process of claim 14, wherein the solution is applied to the metal substrate by dipping.

16. The process of claim 15, wherein the dipping is performed at a temperature between about 25 and about 35° C. and for a length of time between about one minute and about five minutes.

17. The process of claim 13, wherein the alkanethiol is selected from the group consisting of hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, and octadecanethiol.

18. The process of claim 13, wherein the non-organic solvent is water.

19. The process of claim 18, wherein the alkanethiol is dodecanethiol and the surfactant is sodium dodecyl sulfate.

20. The process of claim 13, wherein the metal substrate is a printed circuit board or a component of a printed circuit board.

21. The self-assembled monolayer formed by the process of claim 13.

22. A method of preserving the solderability of a metal surface of a printed circuit board comprising forming a self-assembled monolayer on the metal surface.

23. The method of claim 22, wherein the self-assembled monolayer comprises an alkanethiol.

24. The method of claim 22, wherein the metal surface comprises a final finish.

25. The method of claim 24, wherein the final finish is selected from the group consisting of Electroless Nickel, Electroless Palladium, Electroless Nickel/Immersion Gold (ENIG), Electroless Nickel/Electroless Palladium (ENEP), Electroless Nickel/Electroless Palladium/Immersion Gold (ENEPIG), and Immersion Silver.
